(19) United States
(12) Patent Application Publication
(10) Pub. No.: US 2007/0042119 A1
(43) Pub. Date: Feb. 22, 2007

(54) Vaporizer for atomic layer deposition system

(76) Inventors: Larry Matthysse, Sunnyvale, CA (US); Xinye Liu, Sunnyvale, CA (US); M. Ziaul Karim, Sunnyvale, CA (US); Thomas E. Seidel, Sunnyvale, CA (US)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/351,366

(22) Filed: Feb. 10, 2006

Related U.S. Application Data
(60) Provisional application No. 60/652,422, filed on Feb. 10, 2005.

(51) Int. Cl. C23C 16/00

(52) U.S. Cl. 427/248.1; 118/715

(57) ABSTRACT

A multi-stage precursor vessel system for an atomic layer deposition (ALD) system in which a precursor is transferred from a first, low temperature reservoir chamber into a second (or subsequent) chamber at higher temperature, which second (or subsequent) chamber is used to create a highest possible vapor pressure of the precursor allowed by its temperature without decomposition in the timeframe of its residence therein.

### RELATED APPLICATIONS

The present application is a NONPROVISIONAL of, claims priority to, and incorporates by reference U.S. Provisional Patent Application 60/652,422, filed Feb. 10, 2005.

### FIELD OF THE INVENTION

The present invention relates to a vaporizer for an atomic layer deposition (ALD) processing system in which a liquid precursor is transferred from a first, low temperature reservoir chamber into a second chamber at higher temperature, which second chamber is used to create a highest possible vapor pressure of the precursor allowed by its temperature without decomposition in the timeframe of its residence in the second chamber.

### BACKGROUND

One of the key applications of ALD technology is to conformally coat high aspect ratio structures, such as capacitor structures contained in dynamic random access memory (DRAM) devices. The theory describing the success criteria for uniform deposition in high aspect ratio structures substantially requires the delivery of a sufficient chemical dosage. The required dosage is progressively larger for higher aspect ratio structures. The chemical dose for a successful coating is defined by the product of the number of chemical molecules exposed to the surface for a certain time. This, in turn, is proportional to the product of the partial pressure of the chemical, P, and the exposure time, tₑₓ, (P×tₑₓ).

The partial pressure of a chemical precursor is dependent on the temperature of the source gas that is to be delivered to the reaction chamber and the reacting wafer surface. For liquid sources, the vapor pressure above the liquid increases monotonically with the liquid temperature. However, there is a limit to the temperature that the liquid can be held at since precursor decomposition at higher temperatures inevitably takes place. Once precursor decomposition takes place, the chemical precursor is no longer suitable for its intended chemical reaction.

There are several consequences which follow from the above; for example:
a. if the decomposed chemical products are less volatile than the host chemical, then less chemical is available for delivery; alternatively
b. if the decomposed chemical products have the same or larger volatility than the host chemical, then the decomposed products can transport to the reaction chamber and provide reaction pathways in the gas phase or depositions on the substrate surface that are different than the pure ALD process intended.

One example of the decomposed product driven reactions are (undesired) chemical vapor deposition (CVD) reactions that occur in parallel with the (desired) ALD reactions. This behavior may provide larger deposition rates than ALD, but the additive CVD component may not be conformal on high aspect ratio structures, especially if the CVD components have gas phase reactions.

Based on the above, the present inventors have determined that what is needed is an approach that utilizes a maximum temperature of the precursor, and yet does not permit deleterious precursor decomposition.

### SUMMARY OF THE INVENTION

An embodiment of the present invention provides a multi-stage precursor vessel system for an ALD system in which a precursor is transferred from a first, low temperature reservoir chamber into a second (or subsequent) chamber at higher temperature, which second (or subsequent) chamber is used to create a highest possible vapor pressure of the precursor allowed by its temperature without decomposition in the timeframe of its residence therein.

A further embodiment of the present invention provides an ALD system, including a first reservoir chamber configured to store a precursor at a first, lower temperature, and a second chamber fluidly coupled to the first reservoir chamber and configured to store the precursor at higher temperature, which higher temperature permits a highest possible vapor pressure of the precursor allowed by its temperature without decomposition during residence of the precursor in the second chamber. The second chamber may be fluidly coupled to the first reservoir chamber through a control volume, and a master reservoir may be fluidly coupled to provide the precursor to the first reservoir chamber.

In some cases, the first reservoir chamber may be located on a reactor lid of the ALD system, or, more generally, a few tens of centimeters from the second chamber. Also, in some cases a buffer may be fluidly coupled between the second chamber and a reactor chamber of the ALD system. The first reservoir chamber may be configured to store a quantity of the precursor approximately ten times that which is delivered from the second chamber to a reaction chamber of the ALD system during an ALD process.

In a further embodiment of the invention a precursor is transferred from a first reservoir chamber of an ALD system to a second chamber thereof, wherein the precursor is maintained at a first, lower temperature in the first reservoir chamber and at a second, higher temperature in the second chamber, the second, higher temperature being that temperature which permits a highest possible vapor pressure of the precursor allowed by its temperature without decomposition during residence of the precursor in the second chamber. The precursor may then be transferred at approximately its highest possible vapor pressure from the second chamber to a reactor chamber of the ALD system. The transfer of the precursor from the first reservoir chamber to the second chamber may be made through a control volume at a temperature intermediate that of the first reservoir chamber and the second chamber.

An further embodiment of the present invention provides a multi-stage precursor vessel system for an ALD system in which a precursor is transferred from a first, low temperature reservoir chamber into a second (or subsequent) chamber at higher temperature, which second (or subsequent) chamber is used to create a highest possible vapor pressure of the precursor allowed by its temperature without decomposition in the timeframe of its residence therein. The second chamber at higher temperature produces the highest possible vapor pressure of the precursor allowed by its temperature without decomposition and this vapor can be transferred to an ALD reaction chamber using pulsed or regulated volume.

### BRIEF DESCRIPTION OF THE DRAWINGS

The present invention is illustrated by way of example, and not limitation, in the figures of the accompanying drawings, in which:

FIG. 1 illustrates an ALD system including a multi-stage precursor vessel system configured in accordance with an embodiment of the present invention;

FIG. 2 graphically illustrates the effect of temperature on the decomposition rates of precursors;

FIG. 3 graphically illustrates the effect of temperature on the deposition rates achieved by ALD systems configured in accordance with the present invention; and

FIG. 4 shows another example of a multi-stage precursor vessel system configured in accordance with an embodiment of the present invention.

### DETAILED DESCRIPTION

In light of the problems posed by conventional ALD technologies, the present inventors have recognized the need for a vapor delivery method and system that maximizes the vapor pressure of an otherwise low vapor pressure chemical precursor, but which does not permit decomposition of the same, otherwise thermally unstable, chemical precursor. In one embodiment then, the present invention provides a vaporizer for an ALD processing system in which a liquid precursor is transferred from a first, low temperature reservoir chamber into a second chamber at a higher temperature. The second chamber is used to create the highest possible vapor pressure for the precursor allowed by its temperature, without decomposition in the timeframe of its residence in the second chamber.

These and other examples of the present invention discussed herein are not, however, intended to limit the more general scope of the invention as reflected in the claims following this description. For example, there are many chemical precursors with a vapor pressure that is too low to successfully meet the conformal dose (partial pressure) requirements for the ALD coating of advanced, high aspect ratio, capacitor structures. Specific examples include tetrakis-ethylmethylamino hafnium (TEMAH) and tetrakis-ethylmethylamino zirconium (TEMAZ) for the introduction of Hf and Zr, for the formation of HfO₂ and ZrO₂, respectively. These precursors are specific examples of the general case and we need not limit the class of applications of the present invention to these precursors. Moreover, although the following discussion focuses primarily on liquid precursors, solid precursors dissolved in a solvent may, in principle, be used as well. Note that chemical precursors other than TEMAH and TEMAZ which are suitable for use in connection with the present invention include without limitation: TEMAS, TDMAH, TDMAZ, TDEAH, TDEAZ, and the like.

For liquid sources, the vapor pressure above the liquid monotonically increases with increasing temperature of that liquid. As an example, semi-quantitatively as a rule-of-thumb, for many common liquid sources the vapor pressure may approximately double for every 10° C. rise in temperature. However, at sufficiently high temperature and over a certain time the chemical precursor will undergo thermal decomposition.

To avoid such thermal decomposition and achieve a maximum vapor pressure for a precursor of interest, the present invention provides a two-stage (or, more generally, a multi-stage) precursor vessel system to permit the delivery of the precursor at its maximum (or near maximum) vapor pressure without significant thermal decomposition. In one embodiment, an ALD system configured in accordance with this invention may include a master (or remote) reservoir that holds a relatively large quantity of chemical precursor at low enough temperature that a negligible amount of the precursor decomposes over an, essentially, unlimited time period. The quantity of precursor in the master reservoir may be such that its usage would call for refill only over a relatively long period of time (in terms of the operational cycle of the ALD system), for example a several month, semi-annual or annual basis. In one example, this may be approximately 50 liters. This chemical may be stored at or near room ambient temperature or a controlled temperature below room temperature. The master reservoir may be considered part of a larger “facility”.

Referring now to FIG. 1, the master reservoir (not shown) is used to fill a first, local reservoir 10 in the multi-stage delivery system, for example through a valve V1. As illustrated, the local reservoir 10 may be staged between the master reservoir and a second stage delivery vessel, vaporizer 12. Vaporizer 12 is in fluid communication with reservoir 10 via piping 14, which is bounded by valves V2 and V4. Optionally, a control volume 14 may be located between these valves to facilitate the metering of a specified amount of precursor chemical to the vaporizer 12 from reservoir 10. The amount of liquid in the control volume 16 (more precisely 16+14) may be selected to be a fixed volume, such as 9 cc or 50 cc, etc. Additionally, an optional bypass line 18 from the master reservoir may be provided as an input to control volume 16 via valve V3. As such, the master reservoir may be used as the first chamber in accordance with the methods and systems of the present invention.

Reservoir 10 is preferably located close to the reaction chamber of the ALD system (not shown in detail), and may be placed for example on the reactor lid. The actual quantitative criteria for the distance between the reservoir 10 and the vaporizer 12 is determined by a number of factors, including operability, time to transfer, access, and maintainability, but in a practical case may be tens of centimeters.

Reservoir 10 may store a quantity of precursor on the order of approximately ten times more than that which is delivered, at maximum temperature and partial pressure, from the vaporizer 12 to the reaction chamber. In one embodiment, the vaporizer 12 is configured to contain 50 cc, so the reservoir 10 may contain 500 cc. Carrier gas may be introduced to the vaporizer 12 via valve V5 which couples a carrier gas reservoir (not shown) to the vaporizer 12. The carrier and precursor may be introduced to the reaction chamber via valve V6. The effect of the carrier gas may be to increase the total pressure of the precursor injected charge, however, in various embodiments of the invention, it may be preferable to inject undiluted chemical dosage at higher pressure.

The temperature of the reservoir 10 may be intermediate to that of the master (“cold”) reservoir and the “hot” vaporizer 12, allowing for optimal temperature equilibration time for the precursor to be transferred into the vaporizer. In one embodiment of the present invention (discussed in the example below), the temperature of the reservoir 10 is approximately 50-100° C. The 500 cc of precursor in reservoir 10 would be substantially used in a time period that is short compared to the decomposition period at the reservoir 10 storage temperature.

Reservoir 10 and vaporizer 12 together constitute an example of a two-stage precursor delivery system. When the time to refill the vaporizer 12 becomes operationally limiting (described further below), a second, third or further number of “parallel” vaporizer vessels may be used. Their readiness to deliver high pressure chemical precursor may be time phased with their loading for more rapid continuous ALD deposition operations.

Reservoir 10 may be held at relatively low temperature, but the vaporizer 12 may be held at the highest temperature possible to provide high vapor pressure but specifically designed such that a negligible amount of precursor is decomposed over the period of use of all the precursor volume delivered from the vaporizer. The present two-stage vessel design thus optimizes the pressures, temperatures and transfer times between the reservoir 10 and vaporizer 12 to deliver a maximum partial pressure of the chemical precursor without significant decomposition thereof.

The kinetics of precursor decomposition and the times it takes for decomposition to take place relative to the deposition time on the substrate is important to understand. In ALD processes, the deposition time may vary from a few seconds for a single layer up to a few minutes for a film of approximately 100 Å, or few hours for a “lot” of, say, 25 wafers. Thus, depending on the choice of deposition time and its interval(s) and the amount of time for the delivery of the precursor from the reservoir 10 to the vaporizer 12, one may select different optimized temperatures at which to operate the vaporizer. The optimized temperature is ultimately a function of the decomposition characteristics of the chemical precursor and the time required for the total deposition on the wafer or wafers under consideration.

To better understand this point, consider that the quantity of chemical contained in the vaporizer 12 may be selected to be sufficient to deposit films on device structures on large (e.g., 300 mm) wafers. For example, 2 cc per wafer of TEMAH may used for deposition onto DRAM wafers with very high aspect ratio capacitor structures. If one assumes 25 wafers should be processed without replenishment of the vaporizer, then 50 cc of material will be needed in the vaporizer 12 at the start of the operation. Assume further that the reservoir 10 contains 500 cc at 75-100° C., the control volume 16 is sized at 50 cc at a temperature of 75-100° C. (nominally the same as or intermediate to the reservoir 10), and the vaporizer is set at 115-125° C. for the highest operational temperature for TEMAH chemistry.

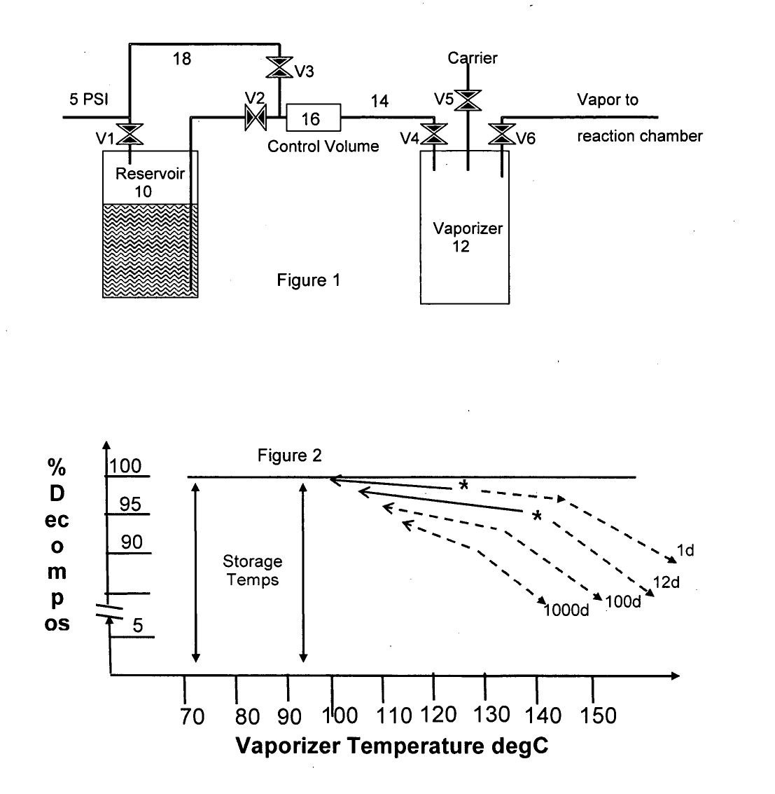

The decomposition of TEMAH has been studied, and Gordon reports the onset of discoloration (est. ˜1%) in 24 hr at 125° C. (note, the discolored precursor did not show any measurable difference in nuclear magnetic resonance spectrum or vapor pressure or the properties of the grown films; however, the discoloration could be a sign of decomposition, which we arbitrarily set at ˜1%). Unfortunately definitive kinetics of TEMAH decomposition are not publicly available, but the trends are clear. FIG. 2 shows a qualitative mapping of these kinetics in which the percentage decomposition is plotted against the vaporizer temperature.

The curves in FIG. 2 indicate safe storage temperature regions, even for the reservoir 10, in this case and the trends in decomposition for 1 day, 12 days, 100 days and 1000 days. The asterisks are the point data reported by Praxiar and Gordon, and the dashed curves are rough estimates of the decomposition trends. While it cannot be stated for certain, these curves should follow an exponential law, where the percentage decomposed is proportional to e^{t/τ(T)}, where τ, the time constant for decomposition, is exponentially dependent on a thermally activated energy.

The vaporizer 12 is designed to deliver precursor vapor while keeping most of the precursor at a sufficiently low temperature that it will not decompose. To load the precursor, the vaporizer 12 and the control volume 16 are evacuated. Next, valve V4 is closed, and valves V1 and V2 are opened to introduce the liquid from reservoir 10 into the control volume 16. Valve V2 is then closed and valve V4 opened, allowing the liquid in control volume 16 to be pulled into the vaporizer 12. Finally, valve V3 is opened to push any liquid remaining in the control volume 16 into the vaporizer 12. After the loading, the vaporizer 12 is at high pressure (e.g., 5 PSI), and it is necessary to bleed off this pressure before beginning an ALD process.

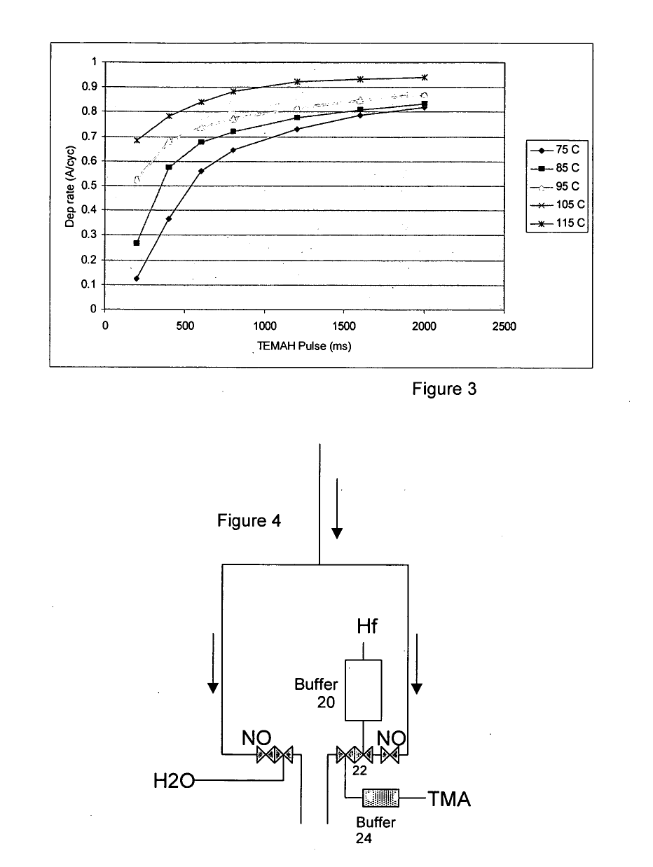

Saturation data at different TEMAH source temperatures was collected. It showed (see FIG. 3) that the deposition rate (Å/cycle) increased with an increase in the source temperature. Further, at higher source temperatures more precursor vapor was delivered into the reaction chamber. The data reported in Table 1 relates to the improved deposition rate for the HfO₂ film observed for a system configured in accordance with an embodiment of the present invention. At various vaporizer temperatures, the deposition rate reached approximately 80% of the maximum deposition at various times according to the schedule.

TABLE 1

| Vaporizer | Time to reach | Time to reach |
|---|---|---|
| Temp (° C.) | 0.7 A/cycle (msec) | 0.80 A/cycle (msec) |
| 115 | 350 | 500 |
| 105 | 500 | 800 |
| 95 | 700 | 1000 |
| 85 | 1000 | 1500 |
| 75 | 1300 | 1800 |

an activation energy may be estimated by plotting the times to each these deposition rate values as a function of reciprocal absolute temperature. The physical interpretation of this activation energy is a combination of that of the vapor pressure vs. temperature of the precursor and the surface ALD reaction kinetics, but in this case should be closer to the relationship for the precursor's vapor pressure.

These procedures were used to deposit high aspect ration DRAM structures with conformal coatings and to achieving approximately 100% step. Source vaporizer temperature approximating 125° C. for TEMAH vapor into the reaction chamber may provide even better deposition characteristics for 300 mm, high aspect ratio, sub-100 nm design rule capacitors.

A further embodiment of the present invention involves the use of a gas delivery manifold configured to reduce precursor (e.g., TEMAH) pulse time by reducing the precursor vapor transport time (i.e., the transport time between the vaporizer and the reaction chamber). As illustrated in FIG. 4, in order to reduce this segment of the vapor transport time a buffer 20 (e.g., 250 cc for storing TEMAH vapor) is introduced immediately next to a vapor delivery valve 22. In this arrangement, the vapor does not have to travel from the vaporizer (not shown) to the injection nozzle through a moderately long connecting (e.g., ¼″) tubing. The residence time for transfer of reactant vapor from the vaporizer is substantially reduced, while the buffer 20 maintains constant communication with the vaporizer. There is only one valve between the vapor and the injection nozzle to the reaction chamber. A smaller buffer 24 may used for TMA considering that TMA has much higher vapor pressure. No buffer was used for the H₂O, due to its higher vapor pressure at the room temperature.

The value of the approaches described herein may ultimately depend on any associated reduction in Cost of Ownership (COO), or $/wafer. The total COO in this regard may be deemed to be the cost to run the equipment plus the cost of consumables used thereby, e.g., precursor chemicals. The productivity of the equipment is related directly to the throughput, which is favorably related to the increase in chemical vaporizer pressure achieved in accordance with the present invention. In a typical application, the COO is $5/wafer=$4 (equipment)+$1 (chemical). If the pressure is increased by a factor of 4× by the design (+20° C. over control), the gross throughput is increased by 4×, but actual net throughput is increased by approximately 2× because of the overhead related to equilibration time, wafer transport and purge times in the ALD processes. The COO therefore would be ˜$2(equipment)+$1 (chemical), if there were no penalty for using the additional chemical in accordance with the present methods.

However, the chemical usage may be adversely increased because we operate close to decomposition. If the residual chemical in the vaporizer becomes progressively enriched in decomposed precursor, after some operational cycles the charge will have to be vented to waste. If we assume that we operate in a condition that requires 50% more chemical usage and have no reclaim operations, then COO is still favorable, but the benefit is reduced. Other cases can be developed, but it is clear that there is a trade off between the benefits of increased throughput and increased chemical usage that has to be managed.

There is also consideration required to manage the amount of dose delivered from the vaporizer to be substantially constant, so as to keep the ALD exposure process in saturation. The use of considerable chemical from a given initial vaporizer charge decreases the partial pressure of the precursor and ultimately an insufficient dose to stay in saturation will remain, unless the vaporizer is frequently recharged. Additionally, setting the dosage very high into saturation to avoid falling out of saturation is chemically wasteful. A compromise may be to set the initial dose 10-20% above the onset of ALD saturation and effect a replenishment of the vaporizer after 10-20% of the initial charge is used to maintain a desirable, nearly constant dose delivery. These considerations are manageable and within the skill of those practicing in the art. In one embodiment of the invention, the dose is controllable through appropriate operation of valve V6.

The multi-stage precursor vessel system described herein may be used in combination with other advancements in ALD systems. For example, the multi-stage precursor vessel system may be used in ALD systems configured with so-called fast-switching throttle valves, as described in co-pending U.S. patent application Ser. No. 10/791,030, filed Mar. 1, 2004, assigned to the assignee of the present invention and incorporated herein by reference. Moreover, the time-phased multi-level flows described in that co-pending application may be used with a precursor system configured substantially as discussed above.

At the outset of this discussion it was noted that what is needed is a system and approach that utilizes a maximum temperature of the precursor and yet does not permit decomposition of the precursor. To develop an understanding of what conditions to design the “last high temperature vaporizer vessel volume” (LV) (whether using the “buffer or the vaporizer” designs discussed above), we consider the case study of using 2 cc of liquid precursor to conformally coat a 300 mm high aspect ratio device wafer. In an ideal ALD process we define a constraint that we want dose control such that all doses are substantially the same within a few percent of one another (e.g., 0.5-3%), and the absolute value of the dose is selected to be approximately 10% higher than that needed for ALD saturation. This condition provides an efficient use of precursor. To better appreciate why this is so, consider the alternatives: If pulses are overdosed, then some precursor is not used in a saturating ALD processes and the excess precursor is discarded. If precursor dose values are less than required for saturation, self-saturating processes are not assured, which may adversely impact conformality of the layer(s).

The dose of each cycle in an advanced single reactor ALD system may take place in a period of approximately 0.1 to 1 sec and the dose for the case study above should be metered to deliver between 0.02+/−3% cc/cycle. This metered dose would be repeated to build the desired thickness of the film, if the deposition/cycle is 1 Å and we desire a 100 Å film, then 100 cycles would be required, and an amount of approximately 2 liquid cc of precursor would be used to build the film.

To do this the dosage removed from the LV may be replenished after a number of cycles that removes up to about 3% of the initial LV chemical charge value. It is easy to see that replenishment after essentially every cycle may be desired. This may be done by selectively opening valves upstream of the LV after each cycle, where the upstream pressure of a larger reservoir volume or control volume is pressure controlled to be nominally constant and corresponds to the initial pressure in the LV. Pressure equilibration with the LV is then assured and the LV is always prepared for removal of successive pulses with the same initial pressure. In practice, the pressure in the control chamber will oscillate a few percentage points around the desired value because it too will need to be recharged from still larger reservoirs maintained upstream of it. This can be done without penalty in the overall cycle time. The repetitive re-charging is done during the period of the purges or the pulsing of the other precursor and the hottest LV's gas comes to equilibrium pressure in a time short with respect to the purges and the other pulse timing.

Two important questions are how high a temperature the LV can be held at and what fraction of precursor is allowed to decompose after one or many wafer depositions. One wafer is picked as a special case study because after one wafer an interval of a timeframe of minutes exists (e.g., while a new wafer is brought into the reaction chamber), allowing for major re-setting of equilibrium conditions. The same is true after a lot of (e.g., 25) wafers, although with continuous operation similar times are available between the last wafer of a one lot and the first wafer from the next lot.

The percent or degree of decomposition acceptable in the LV after the deposition of one wafer may be defined and may be determined empirically. At some percentage greater than X % decomposition, the film specifications will fail. The film is either non-conformal, has leaky characteristics or is non-uniform, etc. because of the presence/effect of decomposed precursor (e.g., producing CVD instead of ALD deposition). At a percentage less than that, with some process control margin, the maximum X % decomposition permitted may be defined.

Here, we define X as the allowable precursor decomposition percentage where the film fails its specification requirements because the LV precursor was held above a “fail temperature for a fail time”. For every X, and a particular ALD process time, there is a corresponding highest allowable LV temperature, Tₘₐₓ.

The issue of progressively additive decomposition within the LV must also be managed. Because the LV will become progressively enriched in decomposed precursor, as more wafers are processed the later wafers to be processed may fail, while the earlier wafers would meet specification. Thus the definition of X may be determined by an iterative procedure. For example, if after the (successful) processing of N wafers at a given high temperature for the vaporizer the (N+1)^{th} and subsequent wafers fail, then the progressive effect is defined. At this number of wafers to provide margin at some number less than N, the charge in the LV should be discarded and a fresh charge introduced. It is possible (even likely perhaps) that some good (i.e., non-decomposed) precursor may ultimately be discarded with the bad, however the overall economics of the approach will determine the maximum allowable LV temperature. The value of higher throughput should be more than the cost of the discarded precursor to represent a commercially viable approach.

As an example, suppose a maximum allowable temperature is chosen that results in 109 wafers passing specification. By evaluation, after 110 wafers, film specification failure occurs. It would then be prudent to discard the LV charge after 100 wafers, and restart the process with pure precursor. If the LV held 2 cc, and 200 cc of depositions were completed, there is only a negligible 1% penalty for discarding the precursor. If the contribution to Cost of Ownership from precursor usage can be traded off against the cost of improved throughput the process is sound. If the precursor usage is low, more can be discarded and the throughput can be increased. If the cost is high for precursor, schemes for the recovery of unused and discarded precursor may allow even more aggressive LV temperatures.

In addition to the foregoing, a vaporizer suitable for use in accordance with the present invention can be configured in such a way that the precursor delivery to the ALD reaction chamber can be continuous and the dose amount maintained by pulsing of valve V6 (or an equivalent thereof). In another embodiment, the vaporizer can be time-pulsed using different techniques.

Thus, a vapor delivery method and system for ALD processes that maximizes the vapor pressure of an otherwise low vapor pressure chemical precursor, but which does not permit decomposition of same, has been described.

What is claimed is:

1. An atomic layer deposition (ALD) system, comprising a first reservoir chamber configured to store a precursor at a first, lower temperature, and a second chamber fluidly coupled to the first reservoir chamber and configured to store said precursor at higher temperature, which higher temperature permits a highest possible vapor pressure of the precursor allowed by its temperature without decomposition during residence time of the precursor in the second chamber.

2. The ALD system of claim 1, wherein the second chamber is fluidly coupled to the first reservoir chamber through a control volume.

3. The ALD system of claim 1, wherein the second chamber is operable to be pulsed to introduce precursor vapor into a reactor.

4. The ALD system of claim 1, further comprising a master reservoir fluidly coupled to provide the precursor to the first reservoir chamber.

5. The ALD system of claim 1, wherein the first reservoir chamber is located on a reactor lid of the ALD system.

6. The ALD system of claim 1, wherein the first reservoir chamber is located tens of centimeters from the second chamber.

7. The ALD system of claim 1, further comprising a buffer fluidly coupled between the second chamber and a reactor chamber of the ALD system.

8. The ALD system of claim 1, wherein the second chamber is fluidly coupled to the first reservoir chamber through one or more valves and associated lines.

9. The ALD system of claim 8, wherein the second chamber comprises a vaporizer.

10. The ALD system of claim 9, wherein the vaporizer os fluidly coupled to a reactor chamber.

11. A method, comprising transferring from a first reservoir chamber of an atomic layer deposition (ALD) system to a second chamber thereof a precursor, wherein the precursor is maintained at a first, lower temperature in the first reservoir chamber and at a second, higher temperature in the second chamber, the second, higher temperature being that temperature which permits a highest possible vapor pressure of the precursor allowed by its temperature without decomposition during residence of the precursor in the second chamber.

12. The method of claim 11, further comprising transferring the precursor at approximately its highest possible vapor pressure from the second chamber to a reactor chamber of the ALD system.

13. The method of claim 11, wherein the transfer of the precursor from the first reservoir chamber to the second chamber is made through a control volume at a temperature intermediate that of the first reservoir chamber and the second chamber.

14. The method of claim 11, wherein the transfer of vapor of the precursor generated at the higher temperature in the second chamber is controlled using a pulsed or regulated volume.
